(19) United States
(12) Patent Application Publication
(10) Pub. No.: US 2003/0148624 A1
(43) Pub. Date: Aug. 7, 2003

(54) Method for removing resists

(76) Inventors: Kazuto Ikemoto, Tokyo (JP); Hiroshi Matsunaga, Tokyo (JP); Hidetaka Shimizu, Tokyo (JP); Masaru Ohto, Tokyo (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/352,224

(22) Filed: Jan. 28, 2003

(30) Foreign Application Priority Data
Jan. 31, 2002 (JP) 24858/2002
May 17, 2002 (JP) 142803/2002

(51) Int. Cl. H01L 21/302; H01L 21/461

(52) U.S. Cl. 438/714

(57) ABSTRACT

The method for removing resists of the present invention comprises a step of contacting a copper-containing substrate having a resist layer thereon with a cleaning composition containing 1% by weight or more of hydrogen peroxide and ammonia or ammonium ion; and a step of contacting the substrate thus contact-treated with an organic solvent-containing resist stripping composition, thereby removing the resist layer. The other method for removing resists of the present invention comprises a step of contacting a substrate having thereon a resist layer, preferably a non-ashed resist layer, with a resist stripping composition of pH 5 or more containing 4 to 30% by weight of hydrogen peroxide, 0.01 to 15% by weight of ammonium ion, and 0.01 to 15% by weight of phosphate ion and/or carbonate ion.

### BACKGROUND OF THE INVENTION

1. Field of the Invention

The present invention relates to a method for removing resists for use in the manufacture of semiconductor integrated circuits, liquid crystal panels, organic EL panels, printed circuit boards, etc., particularly relates to a method for removing resists from substrates containing copper and a method for removing non-ashed resists from substrates.

2. Description of the Prior Art

Photoresists have been used in the lithographic technique for producing a wide range of devices such as integrated circuits including IC and LSI, display devices such as LCD and EL devices, printed circuit boards, micro machines, DNA chips, and micro plants.

Recently, copper has come to be used as the low electrical resistance material for semiconductors, particularly, has come to be increasingly used as the wiring material for semiconductors represented by LSI. With the increasing use of copper, a layer of a low relative dielectric constant (low k layer) is used as the insulating material. In the conventional process for manufacturing semiconductors, resists are removed through the ashing step after the dry etching step using a patterned resist. However, the surface of the layer of a low relative dielectric constant is likely to be changed in its properties during the ashing step, resulting in a failure of a resultant circuit to sufficiently perform its function. To remove this drawback, a manufacturing process without the ashing step is demanded. However, the resist after dry etching is difficult to be removed because of a considerable change in its properties. In spite of such a difficulty, the manufacturing process can be made simple and the dimension accuracy of products can be improved by eliminating the ashing step.

Conventionally, alkali stripping compositions comprising an organic alkali and a water-soluble solvent have been used for removing resists from substrates made of a non-copper based material such as aluminum and aluminum alloys. As the organic alkali, amine compounds such as alkanol amines have been dominantly used. For example, U.S. Pat. No. 4,276,186 discloses a stripping composition comprising N-methylpyrrolidone and an alkanol amine. However, the proposed stripping composition is insufficient for removing resists having their properties extensively changed.

As a stripping composition quite effective for removing resists comprising a phenolic hydroxyl-containing compound or an ester linkage-containing compound, a solution comprising an alkanol amine, hydroxylamine, catechol and water has been used (U.S. Pat. No. 5,279,771). However, this stripping composition fails to remove resists sufficiently, if the ashing is omitted, and is very corrosive to copper that is usually used in combination with a layer of a low relative dielectric constant. In addition, hydroxylamine is expensive.

As a method for removing resists having their properties extensively changed, is proposed a treatment by an amine-based resist stripping composition after the treatment by hydrogen peroxide and a chelating agent (Japanese Patent Application Laid-Open No. 11-74180). Since the proposed method is a two-stage process, simplification has been demanded. In addition, the proposed method considers nothing about the corrosion of copper wiring. The study made by the inventors has proved that the proposed method is insufficient for applying to substrates containing copper in view of preventing corrosion and removing resists.

### SUMMARY OF THE INVENTION

An object of the present invention is to solve the above problems in the prior art and provide a method for easily removing resists that are not removed by the sole use of a conventional stripping composition. Another object of the present invention is to provide a method for removing resists that are not ashed.

As a result of the extensive study on the removal of resists on a copper wiring substrate, the inventors have found that resists are easily removed from the substrate by treating the resists with a cleaning composition containing ammonia or ammonium ion and having a hydrogen peroxide concentration of 1% by weight or more, and then with a resist stripping composition.

Further, as a result of the extensive study on the removal of non-ashed resists, the inventors have further found that the non-ashed resists can be effectively removed by an aqueous solution of pH 5 or more containing hydrogen peroxide, ammonium ion, and phosphate ion and/or carbonate ion.

Thus, in a first aspect of the present invention, there is provided a method for removing resists, which comprises a step of contacting a copper-containing substrate having resists thereon with a cleaning composition containing 1% by weight or more of hydrogen peroxide and ammonia or ammonium ion; and a step of contacting the substrate thus contact-treated with an organic solvent-containing resist stripping composition, thereby removing the resists.

In a second aspect of the present invention, there is provided a method for removing resists, which comprises a step of contacting a substrate having resists thereon with a resist stripping composition of pH 5 or more containing 4 to 30% by weight of hydrogen peroxide, 0.01 to 15% by weight of ammonium ion, and 0.01 to 15% by weight of phosphate ion and/or carbonate ion.

### BRIEF DESCRIPTION OF THE DRAWINGS

FIG. 1 is a schematic illustration of a substrate used in Examples 1 to 14 and Comparative Examples 1 to 8; and

FIG. 2 is a schematic illustration of a substrate used in Examples 15 to 24 and Comparative Examples 9 to 12.

### DETAILED DESCRIPTION OF THE INVENTION

(1) First Resist Removal Method

The ammonia or ammonium ion concentration of the cleaning composition used in the first resist removal method is preferably from 10 ppm to 5% by weight, more preferably 0.01 to 1.5% by weight. The removal of resist becomes more efficient in proportion with the ammonia or ammonium ion concentration, but the cleaning composition becomes more corrosive to copper if the concentration is too high.

Examples of the ammonium ion sources include ammonium carbonate, ammonium hydrogencarbonate, ammonium sulfate, ammonium hydrogensulfate, triammonium phosphate, diammonium phosphate, monoammonium phosphate, ammonium nitrate, ammonium borate, ammonium oxalate, ammonium acetate, and ammonium formate. The hydrogen peroxide stabilizer mentioned below serves also as the ammonium ion source.

A hydrogen peroxide concentration less than 1% by weight is not preferable because the removal of resists is little improved and the corrosion of copper is enhanced. The removal of resists is more improved with increasing hydrogen peroxide concentration. However, high concentrations bring danger because the chain decomposition cannot be prevented if hydrogen peroxide starts to decompose. Therefore, the hydrogen peroxide concentration is preferably 32% by weight or less, and more preferably 30% by weight or less in view of preparing the composition easily and ensuring the safety.

To facilitate the removal of resists, the pH of the cleaning composition is preferably 5 or higher. The pH can be adjusted by an alkali such as ammonia and tetramethylammonium hydroxide or an acid such as sulfuric acid and nitric acid, without no specific limitation thereto. A pH lower than 5 results in an insufficient removal of resists and increases the corrosion of copper. A pH higher than 11 may make hydrogen peroxide less stable for a long-term storage. However, if a long-term storage is not required, the pH may exceed 11.

A particularly preferred cleaning composition for use in the present invention is an aqueous solution with a pH of 5 to 11 having an ammonia or ammonium ion concentration from 10 ppm to 5% by weight and a hydrogen peroxide concentration of 1 to 30% by weight.

It is critical for the cleaning composition to contain hydrogen peroxide. Since hydrogen peroxide is instable against metals and lights, the use of a stabilizer is advisable. Examples of the hydrogen peroxide stabilizers include chelating stabilizers such as aminotri(methylenephsphonic acid), 1-hydroxyethylidene 1,1-diphosphonic acid, ethylenediaminetetra(methylenephsphonic acid), diethylenetriaminepenta(methylenephsphonic acid), 1,2-propylenediamine(tetramethylenephsphonic acid), hexametaphosphoric acid, and ethylenediaminetetraacetic acid; and radical trapping stabilizers such as 1,3-butanediol, urea, propylene glycol, phenylurea, quinone, diethylene glycol monomethyl ether, diethylene glycol monobutyl ether, anthranilic acid, and aminobenzoic acid, although not specifically limited thereto.

The concentration of the hydrogen peroxide stabilizer is preferably 0.1% by weight or less for the chelating stabilizer. Higher concentrations of the chelating stabilizer may increase the corrosion of copper. The concentration is preferably 20% by weight or less for the radical trapping stabilizer.

The cleaning composition may further contain a surfactant and an anti-corrosion agent with no adverse effect. The surfactant may be cationic, anionic or nonionic. These additives may be added in consideration of the surface tension, the corrosion resistance and the cleaning efficiency. Examples of the anti-corrosion agents, particularly those for copper, include azole compounds such as benzotriazole, alkyne compounds such as acetylene alcohols, and low valent sulfur compounds such as thiourea and mercaptothiazole.

In the present invention, the removal of resists is easily effected in a short period of time by the treatment with the cleaning composition containing hydrogen peroxide and the subsequent treatment With the resist stripping composition containing an organic solvent.

The type and the chemical composition of the organic solvent-containing resist stripping composition are not critical in the present invention, and an amine-containing resist stripping composition is preferably used because of its high resist stripping effect. Particularly, a stripping composition containing a quaternary ammonium hydroxide is preferable because it is effective for removing resists having their properties changed. Examples of the amines, but not limited to, include ethanolamine, 1-amino-2-propanol, 1-amino-3-propanol, 1-amino-4-butanol, aminoethoxyethanol, 1-methylaminoethanol, 1,1-dimethylaminoethanol, diethanolamine, triethanolamine, diisopropanolamine, triisopropanolamine, ethylenediamine, diethylenetriamine, triethylenehexamine, hexaethylenepentamine, dimethylethylenediamine, hexamethylethylenediamine, pentamethyldiethylenetriamine, methylaminoethoxyethanol, and dimethylaminoethoxyethanol. Amines having a boiling point of 90° C. or higher are preferred. Examples of the quaternary ammonium hydroxides include tetramethylammonium hydroxide, tetraethylammonium hydroxide and choline hydroxide.

Examples of the organic solvents include dimethyl sulfoxide, sulfolane, N-methylpyrrolidone, N,N′-dimethylimidazolidinone, dimethylacetamide, dimethylformamide, ethylene glycol, diethylene glycol, diethylene glycol monomethyl ether, diethylene glycol monobutyl ether, propylene glycol, propylene glycol monomethyl ether, propylene glycol monoethyl ether, and dipropylene glycol monomethyl ether.

The organic solvent-containing stripping composition may further contain an anti-corrosion agent and a surfactant. As the anti-corrosion agents, particularly those for copper, usable are azole compounds such as benzotriazole, alkyne compounds such as acetylene alcohols, and low valent sulfur compounds such as thiourea and mercaptothiazole.

In the resist removing method of the present invention, the non-masked area of an electrically conductive layer made of copper, etc. is etched by using a patterned resist as a mask. Next, the resist is subjected to the contact treatment with the cleaning composition containing hydrogen peroxide. Then, the remaining resist is removed by the organic solvent-containing stripping composition. After etching, the resist may be ashed if desired. Then, the dry etching residue is subjected to the contact treatment with the cleaning composition containing hydrogen peroxide, followed by the treatment with the organic solvent-containing stripping composition to remove the residue.

The temperature for the contact treatment with the cleaning composition containing hydrogen peroxide is usually 20 to 110° C., with lower temperatures of 70° C. or lower being preferred in view of the stability of hydrogen peroxide. The contact treatment time is preferably 0.5 to 120 min. After the contact treatment with the cleaning composition, the substrate being treated may be rinsed with water or alcohol before the contact treatment with the organic solvent-containing stripping composition. Water is optimum as the rinsing liquid. The rinsing step can be omitted, if appropriate. The temperature for the contact treatment with the organic solvent-containing stripping composition is 20 to 120° C., preferably 50 to 80° C., being selected depending on the degree of resist removal. The contact treatment time is preferably 0.5 to 120 min.

The contact treatment with the organic solvent-containing stripping composition is preferably carried out under the conditions of a dissolved oxygen content of 10 ppm or lower. In the presence of a larger amount of dissolved oxygen, oxygen dissolved into the resist stripping composition oxidizes copper. The oxidized copper forms a copper-amine complex to dissolve into the resist stripping composition, thereby promoting the corrosion of copper. A low dissolved oxygen condition can be attained by using nitrogen, argon, hydrogen, etc., with no specific limitation. Nitrogen and argon are preferably used. The low dissolved oxygen condition can be easily attained by increasing the gas-liquid contact, for example, by bubbling a non-oxygen gas into the resist stripping composition or spraying the resist stripping composition into an inert gas.

After the resist removal treatment, the treated substrate may be rinsed with an organic solvent such as alcohol or water. The rinsing liquid is not specifically limited as far as the treated substrate is not damaged.

In the method of the present invention, the resist removal can be regarded to proceed in the following manner. It is assumed that the formation of carbonyl group by oxidation and the increase in the molecular weight by thermal change occur in a resist having its properties considerably changed. The cleaning composition of the present invention is expected to make the resist having its properties changed soluble by increasing its solubility by the addition of ammonia or ammonium ion, the decrease in the molecular weight by the oxidation due to hydrogen peroxide, and the increase in the hydrophilic groups such as carboxylic group. The resist that is made soluble is removed by the subsequent treatment with the organic solvent-containing stripping composition.

The substrate to be treated by the method of the present invention is characterized by containing copper and/or a copper alloy. The substrate may further contain semiconductor and wiring materials such as silicon, amorphous silicon, polysilicon, silicon oxide layer, silicon nitride layer, aluminum, aluminum alloy, gold, platinum, silver, titanium, titanium-tungsten, titanium nitride, tungsten, tantalum, tantalum compound, chromium, chromium oxide, chromium alloy, and indium-tin-oxide (ITO); compound semiconductors such as gallium-arsenic, gallium-phosphorus and indium-phosphorus; dielectric materials such as strontium-bismuth-tantalum; and LCD substrate materials such as glass.

(2) Second Resist Removal Method

The second resist removal method can be applied to the removal of ashed resists, but, particularly effective for removing non-ashed resists.

The resist stripping composition used in the second resist removal method is an aqueous solution of pH 5 or higher containing hydrogen peroxide, ammonium ion, and phosphate ion and/or carbonate ion.

The concentration of hydrogen peroxide is 4% by weight or more. The higher the concentration, the more effective for the resist removal, but, the concentration is preferably 30% by weight or less in consideration of the decomposition of hydrogen peroxide. The concentration is more preferably 5 to 18% by weight. In view of preventing the inclusion of impurities and minimizing the danger of radical generation, it is preferred to add a hydrogen peroxide stabilizer such as chelating stabilizers and radical trapping stabilizers mentioned above, preferably in an amount of 3 ppm to 1% by weight.

The concentration of ammonium ion is 0.01 to 15% by weight, preferably 0.03 to 1% by weight. The total concentration of phosphate ion and carbonate ion is 0.01 to 15% by weight, preferably 0.2 to 15% by weight. The resist stripping composition may contain both or either of phosphate ion and carbonate ion. These ions can be generated by the reaction of ammonia and a free acid such as phosphoric acid and carbonic acid. The phosphate ion may be present as hydrogenphosphate ion or dihydrogenphosphate ion, and the carbonate ion may be present as hydrogencarbonate ion. These ions can be also generated from an ammonium salt such as triammonium phosphate, diammonium phosphate, ammonium phosphate, ammonium carbonate, and ammonium hydrogencarbonate. Also usable as the source for these ions are condensates such as condensed phosphoric acids, ammonium condensed phosphates and ammonium carbamate. Low concentrations of the ions are less effective, while high concentrations may make the resists less soluble and reduce the stability of hydrogen peroxide.

The pH of the resist stripping composition is 5 or more, preferably 7 to 9. The pH can be adjusted by an alkali such as ammonia and tetramethylammonium hydroxide, or an acid such as sulfuric acid, nitric acid and phosphoric acid. The resist stripping composition may contain other ions such as sulfate ion, hydrogensulfate ion, nitrate ion, borate ion, nitrite ion and hydrochlorate ion.

The resist stripping composition may further contain the surfactant and the anti-corrosion agent mentioned above.

In the second resist removal method, the substrate being treated after etching is contacted with the resist stripping composition preferably at 60 to 110° C. for 0.5 to 120 min, preferably without ashing treatment. The contact treatment temperature and the contact treatment time can be selected depending on the degree of resist removal. After the contact treatment with the resist stripping composition, the substrate is preferably rinsed with a super pure water.

The substrate being treated by the second resist removal method may carry, as the low relative dielectric layer, a inorganic-organic composite layer such as FOX, XLK (both available from Dow Corning Co. Ltd.), LKD (available from JSR Co., Ltd.), and Black Diamond (available from Applied Material Co., Ltd.) and an organic layer such as SiLK (available from Dow Chemical Co., Ltd.). The substrate may further contain semiconductor and wiring materials such as copper, copper alloy, silicon, amorphous silicon, polysilicon, silicon oxide layer, silicon nitride layer, aluminum, aluminum alloy, gold, platinum, silver, titanium, titanium-tungsten, titanium nitride, tungsten, tantalum, tantalum compound, chromium, chromium oxide, chromium alloy, and indium-tin-oxide (ITO); compound semiconductors such as gallium-arsenic, gallium-phosphorus and indium-phosphorus; dielectric materials such as strontium-bismuth-tantalum; and LCD substrate materials such as glass. The second resist removal method is preferably applied to a substrate containing copper and/or a copper alloy.

The present invention will be explained in more detail by reference to the following example which should not be construed to limit the scope of the present invention.

### EXAMPLES 1-4 AND COMPARATIVE EXAMPLES 1-3

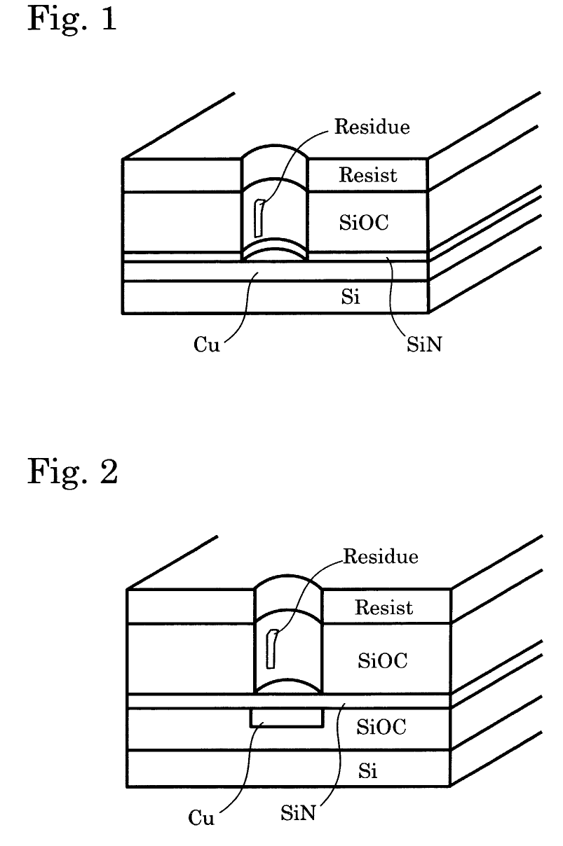

A 300 mm wafer prepared by laminating a copper layer, a SiN layer, a SiOC interlaminar insulating layer and a resist layer in this order on a silicon substrate was subjected to dry etching to form via holes extending to the copper layer. Etching residues remained slightly in the via holes. The substrate after dry etching is illustrated in FIG. 1.

The substrate was treated with the following cleaning composition A and the resist stripping composition B under different treating conditions. After each treatment, the substrate was rinsed with water.

Cleaning Composition A

Hydrogen peroxide: 6% by weight

Ammonia: 0.3% by weight

Balance: water

pH 8.5 (adjusted by sulfuric acid)

Resist Stripping Composition B

Ethanol amine: 5% by weight

Dimethyl sulfoxide: 50% by weight

Propylene glycol: 5% by weight

Tetramethylammonium hydroxide: 0.05% by weight

Balance: water

Dissolved oxygen content: 1 ppm or lower

The removal of resists was observed under a scanning electron microscope, and the results were evaluated by the following ratings.

A: Completely removed

B: Resists were removed, but, residues remained partly

C: Resists remained partly

D: Resists and residues remained unremoved

The treating conditions and the results are shown in Table 1.

TABLE 1
Conditions of Contact Treatment

| | Cleaning | Resist Stripping | |
|---|---|---|---|
| | Composition A | Composition B | Results |
| Examples | | | |
| 1 | 60° C., 20 min | 70° C., 30 min | A |
| 2 | 65° C., 15 min | 70° C., 30 min | A |
| 3 | 50° C., 30 min | 70° C., 40 min | A |
| 4 | 50° C., 15 min | 70° C., 30 min | B |
| Comparative | | | |
| Examples | | | |
| 1 | 60° C., 60 min | — | D |
| 2 | — | 70° C., 30 min | D |
| 3 | — | 80° C., 120 min | C |

### EXAMPLES 5-14 AND COMPARATIVE EXAMPLES 4-9

The experiments were repeated on the similar substrates used in Examples 1-4 and Comparative Examples 1-3 by treating the substrates with the cleaning compositions shown in Tables 2 and 3 at 60° C., and then, treating with the following resist stripping composition:

1-Amino-2-propanol: 28% by weight

N-Methylpyrrolidone: 62% by weight

Tetramethylammonium hydroxide: 1% by weight

Balance: water

Dissolved oxygen content: 1 ppm or lower

at 70° C. for 30 min. The pH of the cleaning composition was adjusted by sulfuric acid and tetramethylammonium hydroxide. After rinsed with water, the removal of resists was observed under a scanning electron microscope, and the results were evaluated in the same manner as above.

Simultaneously, the etching rate (corrosion rate) of copper at 60° C. was measured. The results are shown in Tables 2 and 3. As seen from Table 2, a corrosion of copper that may cause problems in practical use does not occur in Examples 5-14.

TABLE 2

| | | | | | | | Results | |
|---|---|---|---|---|---|---|---|---|
| | Cleaning Composition | | | | | | | Cu |
| | | Ammonium | | | | Treating | | etching |
| | H₂O₂ | source | | Stabilizer | | time | Removal | rate |
| | (wt %) | (wt %) | pH | (ppm) | Balance | (min) | of resist | (Å/min) |
| Exam- | | | | | | | | |
| ples | | | | | | | | |
| 5 | 5 | Ammonia | 10 | — | water | 10 | A | 1.7 |
| | | (1) | | | | | | |
| 6 | 10 | Ammonia | 9.7 | — | water | 5 | A | 0.1 |
| | | (1) | | | | | | |
| 7 | 5 | NH₄NO₃ | 8.8 | — | water | 15 | A | 0.05 |
| | | (0.05) | | | | | | |
| 8 | 5 | (NH₄)₂SO₄ | 8.2 | PDTP | water | 10 | A | 2.7 |
| | | (0.1) | | (100) | | | | |
| 9 | 5 | (NH₄)₂SO₄ | 8.4 | PDTP | water | 10 | A | 1.9 |
| | | (0.4) | | (50) | | | | |
| 10 | 5 | (NH₄)₂SO₄ | 9.4 | NTMP | water | 10 | A | 3.4 |
| | | (0.4) | | (250) | | | | |
| 11 | 5 | (NH₄)₂EDTA | 8.5 | — | water | 15 | B | 0.1 |
| | | (0.02) | | | | | | |
| 12 | 5 | (NH₄)₂SO₄ | 8.6 | DTPP | water | 10 | A | 0.2 |
| | | (0.1) | | (20) | | | | |
| 13 | 3 | (NH₄)HSO₄ | 8.0 | PDTP | water | 15 | A | 0.5 |
| | | (0.2) | | (50) | | | | |
| 14 | 5 | (NH₄)₂CO₃ | 8.5 | — | water | 10 | A | 1.5 |
| | | (0.1) | | | | | | |

PDTP: propanediamine tetramethylenephosphonic acid
NTMP: nitrilotrimethylenephosphonic acid
DTPP: diethylenetriamine pentamethylenephosphonic acid (NH₄)₂EDTA: diammonium ethylenediaminetetraacetate

TABLE 3

| | | | | | | | Results | |
|---|---|---|---|---|---|---|---|---|
| | Cleaning Composition | | | | | | | Cu |
| | | Ammonium | | | | Treating | | etching |
| | H₂O₂ | source | | Stabilizer | | time | Removal | rate |
| | (wt %) | (wt %) | pH | (ppm) | Balance | (min) | of resist | (Å/min) |
| Comparative | | | | | | | | |
| Examples | | | | | | | | |
| 4 | 5 | — | 10 | — | water | 10 | C | 0.7 |
| 5 | — | Ammonia | 9.1 | — | water | 5 | D | 10< |
| | | (1) | | | | | | |
| 6 | 5 | NH₄NO₃ | 3.1 | — | water | 15 | C | 10< |
| | | (0.05) | | | | | | |
| 7 | 5 | (NH₄)₂SO₄ | 8.2 | PDTP | water | 10 | A | 10< |
| | | (0.1) | | (10000) | | | | |
| 8 | 0.1 | (NH₄)₂SO₄ | 8.4 | PDTP | water | 10 | C | 10< |
| | | (0.1) | | (50) | | | | |

### EXAMPLES 15-24

A 300 mm wafer prepared by laminating a SiOC low dielectric layer, a copper layer, a SiN layer, a SiOC low dielectric layer and a resist layer in this order on a silicon substrate was subjected to dry etching to form via holes. Etching residues remained slightly in the via holes. The substrate after dry etching is illustrated in FIG. 2.

After the dry etching, each substrate was contact-treated with each stripping composition shown in Table 4. The pH was adjusted by tetramethylammonium hydroxide and phosphoric acid. The contact treatment was carried out at contact temperatures for contact times shown in Table 4, followed by rinsing with water. The removal of resists was observed under a scanning electron microscope, and the results were evaluated by the following ratings.

A: Completely removed

B: Resists were removed, but, residues remained partly

C: Resists remained partly

D: Resists and residues remained unremoved

The results are shown in Table 4.

TABLE 4

| | | | | | | Treatment | | |
|---|---|---|---|---|---|---|---|---|
| | Stripping Composition | | | | | Conditions | | Results |
| | H₂O₂ | Ammonium | | Stabilizer | | Time | Temp. | Removal |
| | (wt %) | source (wt %) | pH | (ppm) | Balance | (min) | (°C.) | of resist |
| Exam- | | | | | | | | |
| ples | | | | | | | | |
| 15 | 7 | (NH₄)₃PO₄ | 8.7 | PDTP | water | 20 | 80 | A |
| | | (1) | | (50) | | | | |
| 16 | 10 | (NH₄)₃PO₄ | 8.7 | DTPP | water | 25 | 75 | A |
| | | (0.4) | | (20) | | | | |
| 17 | 15 | (NH₄)₃PO₄ | 7.8 | DTPP | water | 15 | 70 | A |
| | | (0.4) | | (20) | | | | |
| 18 | 10 | (NH₄)₃PO₄ | 8.2 | PDTP | water | 35 | 75 | A |
| | | (1) | | (100) | | | | |
| 19 | 9 | (NH₄)₃PO₄ (0.8) | 7.5 | PDTP | water | 20 | 80 | A |
| | | NH₄NO₃ (0.2) | | (20) | | | | |
| 20 | 6 | (NH₄)₂HPO₄ | 9.0 | NTMP | water | 50 | 65 | A |
| | | (3) | | (20) | | | | |
| 21 | 7 | (NH₄)₂CO₃ | 8.5 | EDTA | water | 15 | 90 | A |
| | | (1) | | (80) | | | | |
| 22 | 10 | (NH₄)₂CO₃ | 8.6 | DTPP | water | 20 | 85 | A |
| | | (1) | | (150) | | | | |
| 23 | 6 | (NH₄)HCO₃ | 8.0 | PDTP | water | 60 | 65 | B |
| | | (0.01) | | (50) | | | | |
| 24 | 6 | (NH₄)₃PO₄ | 6.5 | PDTP | water | 45 | 65 | B |
| | | (1) | | (50) | | | | |

PDTP: propanediamine tetramethylenephosphonic acid
NTMP: nitrilotrimethylenephosphonic acid
DTPP: diethylenetriamine pentamethylenephosphonic acid
EDTA: Ethylenediaminetetraacetic acid

### COMPARATIVE EXAMPLES 9-12

The procedures of Examples 15-24 were repeated while changing the stripping compositions and the treating conditions to those shown in Table 5. The results are shown in Table 5.

TABLE 5

| | | | | | | Treatment | | |
|---|---|---|---|---|---|---|---|---|
| | Stripping Composition | | | | | Conditions | | Results |
| | H₂O₂ | Ammonium | | Stabilizer | | Time | Temp. | Removal |
| | (wt %) | source (wt %) | pH | (ppm) | Balance | (min) | (° C.) | of resist |
| Comparative | | | | | | | | |
| Examples | | | | | | | | |
| 9 | 2 | (NH₄)₃PO₄ | 8.4 | PDTP | 20 | 80 | D | |
| | | (1) | | (50) | | | | |
| 10 | 10 | (NH₄)₂SO₄ | 8.7 | DTPP | 25 | 75 | C | |
| | | (0.4) | | (20) | | | | |
| 11 | 30 | — | 6.5 | — | 15 | 70 | D | |
| 12 | 10 | (NH₄)₃PO₄ | 9.2 | — | 35 | 75 | C | |
| | | (0.4) | | | | | | |

According to the first resist removal method of the present invention, the resists as well as etching residues are removed in a short period of time without corroding the substrate containing copper. Particularly, by conducting the contact treatment with the cleaning composition as the pretreatment prior to the treatment with the amine-based resist stripping composition, the resists can be remove without corroding the substrate materials. In the second resist removal method of the present invention, the non-ashed resists as well as etching residues are removed in a short period of time. With this method, the conventional processes requiring the ashing step have been simplified and the working efficiency has been improved.

What is claimed is:

1. A method for removing resists, which comprises a step of contacting a copper-containing substrate having a resist layer thereon with a cleaning composition containing 1% by weight or more of hydrogen peroxide and ammonia or ammonium ion; and a step of contacting the substrate thus contact-treated with an organic solvent-containing resist stripping composition, thereby removing the resist layer.

2. The method according to claim 1, wherein the cleaning composition has a pH of 5 or higher.

3. The method according to claim 1, wherein the cleaning composition contains 10 ppm to 5% by weight of ammonia or ammonium ion.

4. The method according to claim 1, wherein the cleaning composition further contains a hydrogen peroxide stabilizer.

5. The method according to claim 4, wherein the content of the hydrogen peroxide stabilizer is 0.1% by weight or less.

6. The method according to claim 1, wherein the cleaning composition has a pH of 5 to 11, and contains 10 ppm to 3% by weight of ammonia or ammonium ion and 1 to 30% by weight of hydrogen peroxide.

7. The method according to claim 1, wherein the organic solvent-containing resist stripping composition contains an amine.

8. The method according to claim 1, wherein the organic solvent-containing resist stripping composition contains a tertiary ammonium hydroxide.

9. The method according to claim 1, wherein the organic solvent-containing resist stripping composition contains 10 ppm or less of a dissolved oxygen.

10. A method for removing resists, which comprises a step of contacting a substrate having a resist layer thereon with a resist stripping composition of pH 5 or more containing 4 to 30% by weight of hydrogen peroxide, 0.01 to 15% by weight of ammonium ion, and 0.01 to 15% by weight of phosphate ion and/or carbonate ion.

11. The method according to claim 10, wherein the resist stripping composition further contains 3 ppm to 1% by weight of a hydrogen peroxide stabilizer.

12. The method according to claim 10, wherein the resist layer is not ashed.
